(19) United States
(12) Patent Application Publication
(10) Pub. No.: US 2024/0004839 A1
(43) Pub. Date: Jan. 4, 2024

(54) DATA COMPRESSION METHOD AND APPARATUS

(71) Applicant: HUAWEI TECHNOLOGIES CO., LTD., Shenzhen (CN)

(72) Inventors: Jinkang WU, Abu Dhabi (AE); Jianhong TU, Shenzhen (CN); Jianqiang SHEN, Hangzhou (CN); Shaohui QUAN, Hangzhou (CN)

(73) Assignee: HUAWEI TECHNOLOGIES CO., LTD., Shenzhen (CN)

(21) Appl. No.: 18/470,210

(22) Filed: Sep. 19, 2023

Related U.S. Application Data
(63) Continuation of application No. PCT/CN2022/073432, filed on Jan. 24, 2022.

(30) Foreign Application Priority Data
Mar. 30, 2021 (CN) 202110343760.2

(51) Int. Cl. G06F 16/174; H03M 7/30

(52) U.S. Cl. CPC G06F 16/1744; H03M 7/6011; H03M 7/3071

(57) ABSTRACT

Embodiments of this disclosure provide for a data compression method and a related data compression apparatus. In the method, to-be-compressed data and a length limit value for data compression are obtained. When the length of the data obtained by compressing the to-be-compressed data is greater than the length limit value, the to-be-compressed data is segmented based on the length limit value during compression. After the to-be-compressed data is segmented, the to-be-compressed data includes at least two compressed files after compression and a length of each compressed file is less than the length limit value.

### CROSS-REFERENCE TO RELATED APPLICATIONS

This application is a continuation of International Application PCT/CN2022/073432, filed on Jan. 24, 2022, which claims priority to Chinese Patent Application No. 202110343760.2, filed on Mar. 30, 2021. The disclosures of the aforementioned applications are hereby incorporated by reference in their entireties.

### TECHNICAL FIELD

This application generally relates to the data storage field, and in particular, to a data compression method and apparatus.

### BACKGROUND

With the advent of the information age, a large amount of data has been generated for a variety of uses. To make effective use of data in many applications, the data needs to be compressed according to compression algorithms. There may be different mechanisms for compression algorithms based on the application of the data. Some examples of different mechanisms for compression algorithms include duplicate content search, entropy encoding, and the like. The duplicate content search mechanism-based compression algorithms include a Lempel-Ziv (LZ) encoding algorithm, a run-length encoding (RLE) algorithm, and the like. The entropy encoding mechanism-based compression algorithms include a Huffman encoding algorithm, an arithmetic encoding algorithm, and the like.

Currently, during data compression, a compression algorithm is usually used to compress all to-be-compressed data, and a length of the compressed data is unknown before the compression occurs. However, many applications, such as a mail application and a database application, have a length limit for to-be-processed data. Data that does not meet the length limit cannot be processed. For example, for the email application, a transmission error will occur if a length of data exceeds the predetermined limit.

### SUMMARY

Embodiments of this application generally provide for a data compression method. According to the method, when a length of to-be-compressed data after compression is greater than a length limit value, compressed data is segmented based on the length limit value during compression. This allows the compressed data to include a plurality of pieces of sub compressed data, and a length of the sub compressed data is less than the limit value. In this way, data that would conventially exceed the length limit value can now be processed by applications, as the application requirements are now met. Embodiments of this application further provide for an apparatus, a device, a computer-readable storage medium, and a computer program product corresponding to the foregoing method.

According to a first aspect, embodiments of this application provide for a data compression method. The method may be performed by a computer device. The computer device may be a terminal or a server. For ease of description, an example in which the computer device is a terminal is used for description.

Specifically, the terminal obtains to-be-compressed data and a length limit value for data compression. When a length of data obtained by compressing the to-be-compressed data is greater than the length limit value, the terminal segments the to-be-compressed data based on the length limit value for a process of compressing the to-be-compressed data. Accordingly, the to-be-compressed data now includes at least two compressed files after compression, and a length of each compressed file is less than the length limit value.

Even when the length of the data obtained by compressing the to-be-compressed data is greater than the limit value, according to the method, the compressed data can be segmented into a plurality of compressed files whose lengths are less than or equal to the length limit value. In this way, the data can be successfully processed by applications as the application requirements are met.

In some possible implementations, the terminal may predict a length of each compressed data block one by one. The terminal may then accumulate lengths of a currently predicted data block and data blocks prior to the currently predicted block to obtain a first predicted compression length. When the first predicted compression length is greater than the length limit value, the terminal may perform the compression based on the data blocks before the currently predicted data block, where the compressed data forms a first compressed file, and the first compressed file belongs to the at least two compressed files.

A time duration that is passed for predicting the lengths of the compressed data blocks is relatively far less than a time passed for compressing the data blocks and then determining the lengths. Therefore, the lengths are predicted first, then the to-be-compressed data is segmented based on prediction results, and then compression is performed based on segmented data. This method thereby effectively improves compression efficiency.

In some possible implementations, there are N data blocks before the currently predicted data block. Therefore, when the first predicted compression length obtained by accumulating the lengths of the currently predicted data block and the data blocks before the currently predicted data block is greater than the length limit value, the terminal may roll back a data block, and perform merging and compression on some or all data blocks (for example, a first data block to an (N−k)^{th} data block, where N is a natural number greater than or equal to 2, and k is a natural number less than N) of the N data blocks before the currently predicted data block. When a length of the compressed data is less than or equal to the length limit value, the compressed data is used as the first compressed file.

By performing data block rollback when the first predicted compression length is greater than the length limit value, a quantity of compression times can be effectively reduced, thereby improving the compression efficiency.

In some possible implementations, when a length of data obtained by merging and compressing the first data block to the (N−k)^{th} data blocks is less than or equal to the length limit value, the terminal may continue to predict a length of a compressed data block after the (N−k)^{th} data block. The terminal may then continue to segment remaining data of the to-be-compressed data. In this way, repeated compression can be avoided, a computing amount is reduced, and computing resource overheads are reduced.

In some possible implementations, there are N data blocks before the currently predicted data block, and the terminal performs the compression based on the data blocks before the currently predicted data block. Specifically, the terminal may first perform merging and compression on the first data block to the (N−k)^{th} data block, where N is a natural number greater than or equal to 2, and k is a natural number less than N. When the length of the compressed data is greater than the length limit value, the terminal may roll back a data block and perform merging and compression on data blocks after rollback. For example, the terminal may perform merging and compression on a first data block to an (N−k−1)^{th} data block.

Through step-by-step rollback, the quantity of compression times can be reduced, the compression efficiency is improved, and compression overheads are reduced.

In some possible implementations, the to-be-compressed data may be a data stream that is not divided into blocks. The terminal may then perform block division on the data stream to obtain a plurality of data blocks. When a segmentation position of data does not affect the data, the terminal may further perform block division based on the following block division method. This may ensure that a reduction rate is improved while lengths of all compressed files formed by merging and compressing the data blocks do not exceed the limited length.

Specifically, the terminal first performs block division on the to-be-compressed data for a first time. For example, the terminal performs block division according to an average block division method, to obtain a plurality of initial data blocks. The terminal may record boundary values of the plurality of initial data blocks, and the boundary value may be represented by a sequence number of a last byte of the initial data block.

The terminal may further perform matching on the plurality of initial data blocks. For example, the terminal may perform matching according to an LZ encoding algorithm, to obtain a four-tuple of each initial data block. The four-tuple includes inter-block four-tuples, which is specifically a four-tuple generated when different data blocks are successfully matched. When one data block is successfully matched with a plurality of data blocks, the terminal records a four-tuple generated when the data block is matched with a data block closest to the data block. The four-tuple includes an unmatched character sequence, an unmatched character length, a match length, and a match offset. A matched character sequence and a match character sequence may form a match.

The terminal may determine, based on a boundary of the initial data block and a four-tuple (for example, a match offset in the four-tuple) of the initial data block, whether the boundary and the match intersect. When a character representing the boundary is between the matched character sequence and the match character sequence, the boundary and the match intersect. Based on this, the terminal may take statistics of quantities of intersections of boundaries of the initial data blocks and matches. The terminal may select an optimal position for block division based on the quantities of intersections. For example, the terminal may select a boundary having a minimum quantity of intersections with the match or a boundary less than a preset value as the optimal position for block division. The terminal merges, based on the optimal positions for block division, data blocks between the optimal positions for block division, to obtain final data blocks.

When the compression algorithm requires rollback by block division, the rollback is performed based on the optimal position for block division. In this case, data on two sides of the optimal position for block division separately participates in compression. Because a quantity of matches of inputted data that needs to cross the position is small, and lengths of the matches are short, when compression is performed in this block division manner, a loss of an overall compression ratio is smaller compared to that before block division.

According to a second aspect, this application provides a data compression apparatus. The apparatus includes a communication circuit that is configured to obtain to-be-compressed data and a length limit value for data compression. The apparatus also includes a compression circuit that is configured to segment the to-be-compressed data based on the length limit value in a process of compressing the to-be-compressed data when a length of data obtained by compressing the to-be-compressed data is greater than the length limit value. In doing so, the to-be-compressed data includes at least two compressed files after compression, and a length of each compressed file is less than the length limit value.

In some possible implementations, the compression circuit is configured to predict a length of each compressed data block one by one, and accumulate lengths of a currently predicted data block and data blocks before the currently predicted block to obtain a first predicted compression length. The compression circuit is further configured to perform compression based on the data blocks before the currently predicted data block when the first predicted compression length is greater than the length limit value. The compressed data forms a first compressed file, and the first compressed file belongs to the at least two compressed files.

In some possible implementations, there are N data blocks before the currently predicted data block, and the compression circuit is configured to perform merging and compression on a first data block to an (N−k)^{th} data block, where N is a natural number greater than or equal to 2, and k is a natural number less than N. When a length of the compressed data is less than or equal to the length limit value, the compression circuit is further configured to use the compressed data as the first compressed file.

In some possible implementations, the compression circuit is further configured to continue to predict a length of a compressed data block after the (N−k)^{th} data block in order to continue to segment remaining data of the to-be-compressed data.

In some possible implementations, there are N data blocks before the currently predicted data block, and the compression circuit is configured to perform merging and compression on a first data block to an (N−k)^{th} data block, where N is a natural number greater than or equal to 2, and k is a natural number less than N. When a length of the compressed data is greater than the length limit value, the compression circuit is further configured to perform merging and compression on a first data block to an (N−k−1)^{th} data block.

According to a third aspect, this application provides a device. The device includes a processor and a memory. The processor and the memory communicate with each other. The processor is configured to execute instructions stored in the memory that enable the device to perform the data compression method according to the first aspect or any implementation of the first aspect.

According to a fourth aspect, this application provides a computer-readable storage medium. The computer-readable storage medium stores instructions, and the instructions instruct a device to perform the data compression method according to the first aspect or any implementation of the first aspect.

According to a fifth aspect, this application provides a computer program product including instructions. When the computer program product is run on a device, the device is enabled to perform the data compression method according to the first aspect or any implementation of the first aspect.

In this application, the implementations according to the foregoing aspects may be further combined to provide more implementations.

### BRIEF DESCRIPTION OF DRAWINGS

To describe the technical method in embodiments of this application more clearly, the following briefly describes the accompanying drawings used for the embodiments.

FIG. 1 is a schematic diagram of a structure of a terminal according to an embodiment of this application;

FIG. 2 is a flowchart of a data compression method according to an embodiment of this application;

FIG. 3 is a schematic diagram of a graphical user interface according to an embodiment of this application;

FIG. 4 is a schematic diagram of block division of data according to an embodiment of this application;

FIG. 5 is a schematic flowchart of a data compression method according to an embodiment of this application;

FIG. 6 is a schematic flowchart of a data compression method according to an embodiment of this application; and

FIG. 7 is a schematic diagram of a structure of a data compression apparatus according to an embodiment of this application.

### DESCRIPTION OF EMBODIMENTS

In embodiments of this application, the terms “first” and “second” are used merely for the purpose of description, and shall not be construed as indicating or implying relative importance or implying a quantity of indicated technical features. Therefore, features defining “first” and “second” may explicitly or implicitly include one or more such features.

First, some technical terms used in embodiments of this application are described.

Data compression: Data compression is a process of representing information with data bits (or other information-related units) fewer than those without requiring encoding based on a specific encoding mechanism. Data compression is implemented according to the applied data compression algorithms. According to different encoding mechanisms, the data compression algorithms may be classified into different types such as compression algorithms based on a duplicate content search mechanism and compression algorithms based on an entropy encoding mechanism. The compression algorithms based on the duplicate content search mechanism include a Lempel Ziv (LZ) encoding algorithm, a run-length encoding (RLE) algorithm, and the like. The LZ encoding algorithm is used as an example. A compression principle of the LZ encoding algorithm is to traverse inputted data to generate a historical dictionary, and a repeated piece of data is stored in a form of a dictionary index that occupies less space. The compression algorithms based on the entropy encoding mechanism include a Huffman encoding algorithm, an arithmetic encoding algorithm, and the like. The Huffman encoding algorithm is used as an example. A compression principle of the Huffman encoding algorithm is to re-encode characters based on a fact that different characters have different occurrence frequencies in the inputted data to implement compression.

Conventionally, during data compression, a compression algorithm is usually utilized to compress all to-be-compressed data, while a length of compressed data is unknown before compression. However, many applications, such as a mail application and a database application, have a length limit for the to-be-processed data. Data that does not meet the length limit cannot be processed. For example, for the email application, a transmission error occurs if a length of data exceeds the limit. Based on this, the industry urgently needs to provide a data compression method that limits the length of the compressed data, so as to meet application requirements.

An embodiment of this application provides a data compression method. Before data compression, a length limit value of data of an application processing the data is first obtained. When a length of data obtained by compressing to-be-compressed data is greater than the length limit value, compressed data is segmented based on the length limit value in a process of data compression, so that the compressed data includes at least two pieces of sub compressed data, and a length of the sub compressed data is less than the limit value. In this way, even when the length of the data obtained by compressing the to-be-compressed data is greater than the limit value, the data can be successfully processed by the application.

Some embodiments may be applied to different application scenarios. For example, some embodiments may be applied to an email application. The email application has a limit on a size of an email attachment. Assuming that a size of an attachment that is allowed to be uploaded in the email application is within 20 megabytes (MB), an attachment with a size greater than 20 MB may be compressed, and a plurality of compressed files with sizes less than 20 MB are obtained. For another example, some embodiments may be applied to an information management system. The information management system has a limit on a size of an attachment uploaded by a user. In this case, the attachment may be compressed, and the attachment is compressed into a plurality of compressed files with sizes less than the length limit value.

The mail application and the information management system are merely examples for describing an application scenario. The data compression method may further be applied to another scenario in which a length is limited. For example, the method may be applied to a scenario in which a bottleneck occurs in a transmission bandwidth and transmission reliability, or applied to a scenario in which a length is limited due to a storage granularity or a network transmission requirement during video compression or the like.

The data compression method provided in some embodiments may be performed by a computer device. The computer device may be a terminal or a server. The terminal includes but is not limited to a device such as a desktop computer, a notebook computer, a tablet computer, or a smartphone. The server may be a local server (such as a server in a privately owned data center) or a cloud server (such as a server in a data center of a cloud service provider). Further, the method may be performed by a single computer device, or may be performed by a cluster formed by a plurality of computer devices, and stability and reliability of a data compression service can be improved when the method is performed by the cluster.

For ease of understanding, the following uses an example in which a terminal performs the data compression method for description.

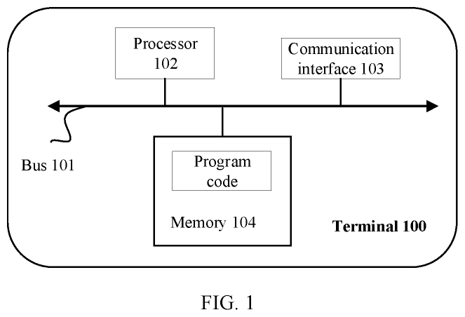

First, a hardware structure of the terminal is described. FIG. 1 is a schematic diagram of a structure of a terminal according to an embodiment of this application. As shown in FIG. 1, a terminal 100 includes a bus 101, a processor 102, a communication interface 103, and a memory 104. The processor 102, the memory 104, and the communication interface 103 communicate with each other through the bus 101.

The bus 101 may be a peripheral component interconnect (PCI) bus, an extended industry standard architecture (EISA) bus, or the like. The bus may be classified into an address bus, a data bus, a control bus, or the like. For ease of description, the bus in FIG. 1 is represented by using only one bold line. However, this does not indicate that there is only one bus or one type of bus.

The processor 102 may be any one or more of processors such as a central processing unit (CPU), a graphics processing unit (GPU), a microprocessor (MP), or a digital signal processor (DSP).

The communication interface 103 is configured to communicate with the outside. For example, the communication interface 103 is configured to obtain to-be-compressed data, obtain a length limit value for data compression, or output at least two compressed files whose lengths are less than the length limit value, or the like.

The memory 104 may include a volatile memory, for example, a random access memory (RAM). The memory 104 may further include a non-volatile memory, for example, a read-only memory (ROM), a flash memory, a hard disk drive (HDD), or a solid-state drive (SSD).

The memory 104 stores executable code, and the processor 102 executes the executable code to perform the foregoing data compression method.

FIG. 1 describes in detail a hardware apparatus for the terminal 100 that is configured to perform the data compression method. The following describes in detail the data compression method provided in this embodiment of this application from a perspective of the terminal 100 with reference to the accompanying drawings.

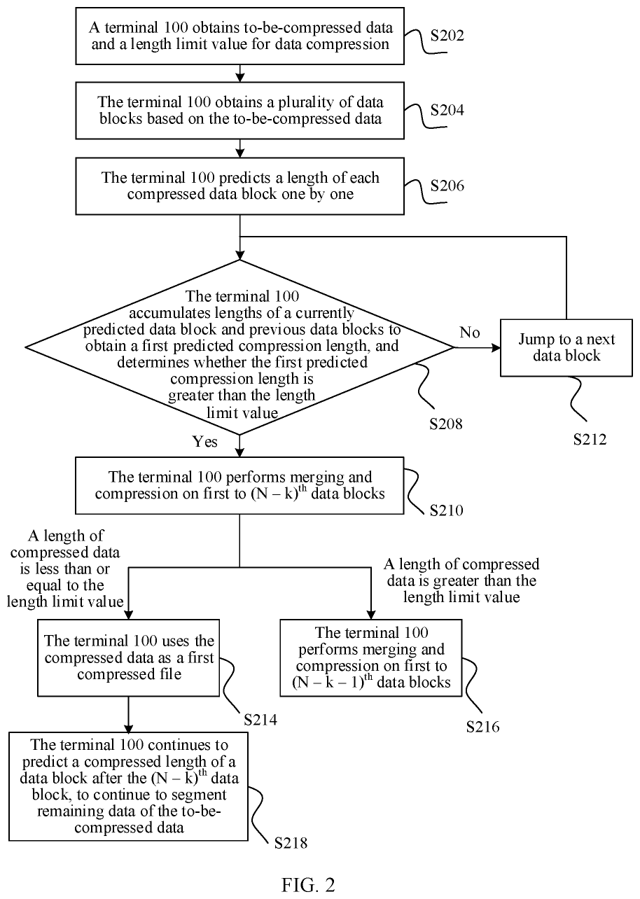

Refer to a flowchart of the data compression method shown in FIG. 2, the method includes:

S202: The terminal 100 obtains to-be-compressed data and a length limit value for data compression.

The terminal 100 may provide a user interface. The user interface may be a graphical user interface (GUI) or a command user interface (CUI). The terminal 100 may receive data inputted by a user through the GUI or the CUI and the length limit value for data compression. The length limit value for data compression is a limit value for a length of the to-be-compressed data after being compressed by an application processing the to-be-compressed data. The terminal 100 may directly receive the data inputted by the user, or may receive a storage path of the data inputted by the user, and then obtain the data according to the storage path.

The following descriptions uses the GUI as an example to describe how the terminal obtains the to-be-compressed data and the length limit value for data compression.

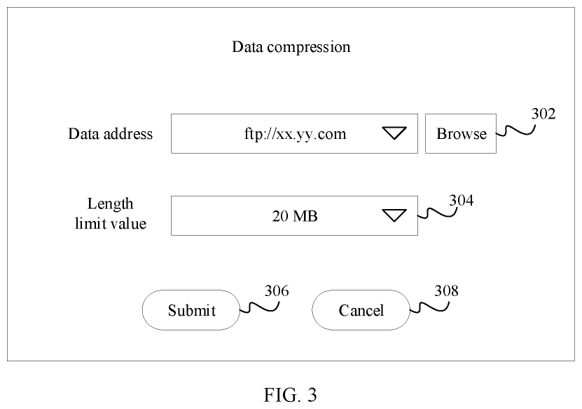

Referring to a schematic interface diagram of the GUI shown in FIG. 3, as shown in FIG. 3, the GUI bears a storage address input control 302 and a length limit value input control 304. The storage address input control 302 is configured to input a storage address of data, and the storage address input control 302 supports a drop-down input manner. The length limit value input control 304 is configured to input a length limit value. The GUI further bears a submit control 306 and a cancel control 308. After inputting the storage address of the data through the storage address input control 302 and inputting the length limit value through the length limit value input control 304, the user may click the submit control 306 to trigger a submission operation. The terminal 100 may obtain the data and the length limit value in response to the submission operation of the user.

It should be noted that, in some embodiments, an application may alternatively set a length limit value by default. In this way, the GUI may not bear the foregoing length limit value input control 304 and the user does not need to configure the length limit value. Instead, the user inputs a storage address of the to-be-compressed data through the GUI. The terminal 100 obtains the to-be-compressed data according to the storage address and obtains the length limit value according to a default setting.

S204: The terminal 100 obtains a plurality of data blocks based on the to-be-compressed data.

The data may include a plurality of data blocks. The plurality of data blocks included in the data may be inherent, or may be obtained by the terminal 100 by performing block division on the data. For example, the terminal 100 may perform average block division on the data based on a quantity of the data blocks or a length of a data block so as to obtain the plurality of data blocks. It should be noted that, when a total length of the data cannot be exactly divided by the quantity of the data blocks or the length of a data block, a length of a particular data block may not be equal to a length of the other data blocks. For example, when the length of the data is 130 kilobytes (KB) and the length of a single data block is 8 KB, the data may be divided into 15 data blocks of 8 KB and a data block of 10 KB.

For a situation in which the data is not explicitly divided into blocks, for example, the inputted data is a consecutive input with a long length, and a segmentation position of the data does not affect the data, some embodiments may further provide a block division method, to improve a reduction rate while all compressed files formed by merging and compressing the data blocks do not exceed a specified length.

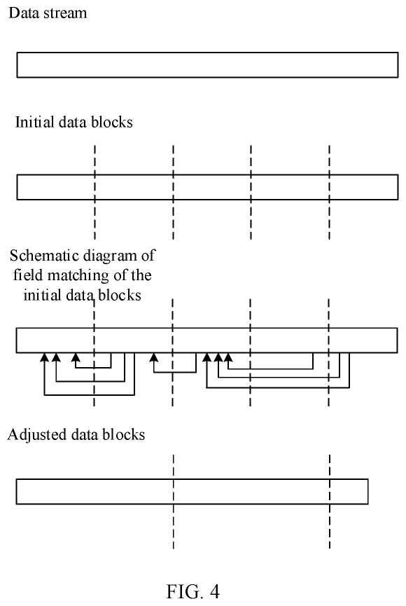

Referring to a schematic flowchart of block division of data shown in FIG. 4, original data is a consecutive data stream, and the terminal 100 may divide the data into a plurality of initial data blocks with an equal size in an average block division manner. The terminal 100 may record boundary values of the plurality of initial data blocks, and the boundary value may be represented by a sequence number of a last byte of the initial data block. Subsequently, the terminal 100 may further perform matching on the plurality of initial data blocks. For example, the terminal 100 may perform matching according to an LZ encoding algorithm, to obtain a four-tuple of each initial data block. The four-tuple includes inter-block four-tuples, which is a four-tuple generated when different data blocks are successfully matched. When one data block is successfully matched with a plurality of data blocks, in some embodiments, a four-tuple generated when the data block is matched with a data block closest to the data block is recorded. The four-tuple includes an unmatched character sequence, an unmatched character length, a match length, and a match offset.

For ease of understanding, this application provides an example. In this example, it is assumed that a length of the data stream is 500 bytes (B). The terminal 100 performs block division based on an average block division method to obtain a plurality of initial data blocks, and boundaries of the initial data blocks are positions 100B, 200B, . . . , 400B, and the like. The data stream and the boundaries of the initial data blocks are specifically as follows:
( . . . QWER . . . XYZ . . . TYUI . . . , (100B), . . . QWER . . . TYUI . . . XYZ . . . , (200B), . . . LMN . . . TYUI . . . OPQ . . . SDF . . . , (300B), . . . LMN . . . , (400B), . . . SDF . . . OPQ . . . )

The ellipsis represents a character that fails to be matched, “QWER” and the like represent characters that are successfully matched, and (100B), (200B), and the like represent the boundaries of the initial data blocks. “QWER” in a first data block is successfully matched with “QWER” in a second data block, “XYZ” in the first data block is successfully matched with “XYZ” in the second data block, “TYUI” in the first data block is successfully matched with “TYUI” in the second data block, “TYUI” in the second data block is successfully matched “TYUI” in a third data block, “LMN” in the third data block is successfully matched with “LMN” in a fourth data block, “OPQ” in the third data block is successfully matched with “OPQ” in a fifth data block, and “SDF” in the third data block is successfully matched with “SDF” in the fifth data block.

The terminal 100 may record, based on the foregoing matching results, quantities of intersections of the boundaries and matches. That a boundary and a match intersect means that a boundary character is between the match characters. Based on this, in the foregoing example, the terminal 100 may determine that a quantity of intersections of the boundary 100B and matches is 3, a quantity of intersections of the boundary 200B and a match is 1, a quantity of intersections of the boundary 300B and matches is 3, and a quantity of intersections of the boundary 400B and matches is 2. The terminal 100 may select an optimal position for block division based on the quantities of intersections of the boundaries and the matches, and merges the initial data blocks based on the optimal position for block division to obtain final data blocks. The terminal 100 may select a boundary having a minimum quantity of intersections with the match or a boundary less than a preset value as the optimal position for block division. For example, the terminal 100 may select 200B as the optimal position for block division. Further, the terminal 100 may alternatively select 400B as the optimal position for block division.

When the compression algorithm requires rollback by block division, the rollback is performed based on the optimal position for block division. In this case, data on two sides of the optimal position for block division separately participate in the compression. Because a quantity of matches of inputted data that needs to cross the position is smallest, and lengths of the matches are shortest, when compression is performed in this block division manner, a loss of an overall compression ratio is smaller when compared to that before block division.

S206: The terminal 100 predicts a length of each compressed data block one by one.

In some possible implementations, when a compression algorithm based on an entropy encoding mechanism is used for the data blocks, the terminal 100 may predict a predicted value of the length of each compressed data block one by one based on a Shannon-Fano entropy limit. The Shannon-Fano entropy limit is calculated according to the following formula:

H(x)=−Σₓp(x)log₂p(x) (1), where
x indicates a character inputted through entropy encoding, p(x) indicates an occurrence probability of the character x, H (x) indicates the Shannon-Fano entropy limit that is a minimum quantity of bits of per inputted byte after entropy encoding. Based on this, the predicted value of the length of the compressed data block can be determined based on an entropy encoding input length (for example, a quantity of bytes) and the Shannon-Fano entropy limit, which is shown as follows:

lenₒᵤₜx=lenᵢₙ*H(x)=lenᵢₙ*(−Σₓp(x)log₂p(x)) (2), where
lenᵢₙ indicates an input length, for example, a quantity of bytes of an entropy encoding input, and lenₒᵤₜx indicates an output length, for example, a predicted value of a length obtained after entropy encoding is performed on an input. It should be noted that, when the terminal 100 directly performs entropy encoding on a data block, the input length may be a length of the data block.

In some possible implementations, the terminal 100 may alternatively first perform matching on the data blocks, for example, perform matching on the data blocks one by one according to an LZ encoding algorithm, to obtain a four-tuple of each data block, and the four-tuple includes an inter-block four-tuple and an intra-block four-tuple. For the inter-block four-tuple, refer to the foregoing related content descriptions. The intra-block four-tuple refers to a four-tuple generated when matching in the data block succeeds. Similar to the inter-block four-tuple, the intra-block four-tuple also includes an unmatched character sequence, an unmatched character length, a match length, and a match offset. The terminal 100 may use the four-tuple as an entropy encoding input to perform entropy encoding, to implement compression on the data block. Correspondingly, the input length may be a length of the four-tuple. The terminal 100 may determine, based on the length of the four-tuple and the Shannon-Fano entropy limit, the predicted value of the length obtained after entropy encoding is performed on the input.

The terminal 100 may separately perform character frequency statistics based on each element (such as the unmatched character sequence, the unmatched character length, the match length, and the match offset) of the four-tuple, that is, a quantity of occurrences of each type of character in each element is counted, and the occurrence probability p(x) of the character x is obtained by dividing the character frequency by a total quantity of the characters. In this way, the terminal 100 may use p(x) to determine the Shannon-Fano entropy limit H(x) according to the foregoing formula (1).

In some possible implementations, the terminal 100 may further manage process data that is generated in a prediction process. The process data may include the four-tuples generated when matching is performed on the data blocks, and boundary information corresponding to the four-tuples of the data blocks. The terminal 100 may store the four-tuples of the data blocks and the boundary information of the four-tuples. The boundary information includes quantities of the four-tuples of the data blocks. For example, the terminal 100 performs matching on a data block and obtains 10 four-tuples. The terminal 100 may store the 10 four-tuples corresponding to the data block and store a quantity (for example, 10) of the four-tuples corresponding to the data block. In this way, the terminal 100 may distinguish four-tuples of different data blocks according to the boundary information, and may further quickly obtain a corresponding four-tuple, to implement a fast data block rollback.

In some other possible implementations, the terminal 100 may further obtain a historical compression rate, and the historical compression rate includes a compression rate of data compression by the terminal 100 before current compression. The compression rate of data compression includes an overall compression rate, and the overall compression rate may provide a reference for a compression rate of the data block. Based on this, the terminal 100 may predict a length of a compressed data block based on a length of the data block and the historical compression rate. For example, the terminal 100 may determine a product of the length of the data block and the historical compression rate as the predicted value of the length of the compressed data block. In some embodiments, the terminal 100 may determine an average value of the historical compression rate. For example, the terminal 100 may determine an average value of overall compression rates of the five latest occurrences of performing compression, and then determine the predicted value of the length of the compressed data block based on the length of the data block and the average value of the historical compression rate.

Further, the terminal 100 may update the historical compression rate, so that the historical compression rate can be close to an actual compression rate, thereby implementing accurate prediction of the length. The terminal 100 may determine a current compression rate based on the length of the data and a length of compressed data of the data, and then update the historical compression rate based on the current compression rate. The updated historical compression rate can be used for a next round of prediction. When managing the historical compression rate, the terminal 100 may adopt a first in first output (FIFO) policy or the like for management.

S208: The terminal 100 accumulates lengths of a currently predicted data block and data blocks before the currently predicted data block to obtain a first predicted compression length, and determines whether the first predicted compression length is greater than the length limit value. When the first predicted compression length is greater than the length limit value, S210 is performed. When the first predicted compression length is less than or equal to the length limit value, S212 is performed.

It is assumed that there are N data blocks before the currently predicted data block. The terminal 100 accumulates predicted compression lengths of the N data blocks and a predicted compression length of the current data block, to obtain the first predicted compression length. When the first predicted compression length is greater than the length limit value, it indicates a high probability that lengths of the N+1 compressed data blocks are greater than the length limit value, and the terminal 100 may perform data block rollback. For example, one data block may be rolled back. In this case, a probability of obtaining a compressed file whose length is less than or equal to the length limit value is high. Based on this, the terminal may perform S210. When the first predicted compression length is less than or equal to the length limit value, it indicates a high probability that the lengths of the N+1 compressed data blocks are less than the length limit value, and the terminal 100 may still add a new data block for being merged and compressed. This arrangement improves an input granularity as much as feasibly possible. Based on this, the terminal 100 may perform S212.

S210: The terminal 100 first performs merging and compression on a first data block to an (N−k)^{th} data block. When a length of compressed data is less than or equal to the length limit value, S214 is performed. When the length of the compressed data is greater than the length limit value, S216 is performed.

N is a natural number greater than or equal to 2, and k is a natural number less than N. For example, a value of k may be 0, 1, or the like. The terminal 100 may merge some or all data blocks of the N data blocks before the currently predicted data block. For example, the terminal 100 may merge the N data blocks, and then implement compression on a merged data block. The terminal 100 may select a corresponding compression algorithm according to an actual requirement, to implement compression on the merged data block. For example, the terminal 100 may select a compression algorithm based on entropy encoding, for example, a Huffman encoding algorithm or an arithmetic encoding algorithm, or select a compression algorithm based on duplicate content search, for example, an LZ encoding algorithm or an RLE algorithm, to implement compression on the merged data block.

When the terminal 100 determines the four-tuples of the data blocks according to the LZ encoding algorithm and predicts the lengths based on the four-tuples of the compressed data blocks, the terminal 100 may use the foregoing four-tuples to perform entropy encoding according to the LZ encoding algorithm so as to implement compression on the merged data block. When the terminal 100 predicts the lengths of the compressed data blocks based on the historical compression rate, the terminal 100 may select the compression algorithm based on entropy encoding or the compression algorithm based on duplicate content search (for example, the LZ encoding algorithm) for encoding so that it may implement compression on the merged data block.

S212: The terminal 100 jumps to a next data block, uses the next data block as the currently predicted data block, and performs S208.

The terminal 100 gradually accumulates predicted compression lengths of new data blocks. When a sum of the predicted compression lengths of the data blocks is less than or equal to the length limit value, the terminal 100 jumps to a next data block, and continues to accumulate. When the sum of the lengths is greater than the length limit value, the terminal 100 may stop accumulating. In this way, the terminal 100 may determine proper segmentation points in these data blocks to segment a plurality of data blocks, and further perform merging and compression on the segmented data blocks.

S214: The terminal 100 uses the compressed data as a first compressed file and then performs S218.

The length of the compressed data is less than or equal to the length limit value, and a small quantity of data blocks are rolled back to be compressed in a case that the predicted compression length is greater than the length limit value. Therefore, the length of the compressed data is close to the length limit value, and the terminal 100 may use the compressed data as the first compressed file. In this way, a length limit value requirement of an applications is met, while preventing a granularity of the compressed file to be excessively small (e.g., relative to the length limit value).

S216: The terminal 100 performs merging and compression on a first data block to an (N−k−1)^{th} data block.

The length of the compressed data is greater than the length limit value, and the terminal 100 may roll back a data block, and then perform merging and compression on data blocks after rollback. The embodiment shown in FIG. 2 is described by using an example of performing merging and compression on the first data block to the (N−k−1)^{th} data block after one data block is rolled back. In another possible implementation of this embodiment of this application, the terminal 100 may alternatively roll back a plurality of data blocks each time, for example, two data blocks may be rolled back.

S218: The terminal 100 continues to predict a length of a compressed data block after the (N−k)^{th} data block, to continue to segment remaining data of the to-be-compressed data.

Because the first data block and the (N−k)^{th} data block have been merged and compressed and the first compressed file is obtained, the terminal 100 may continue to predict a length of a compressed data block after the (N−k)^{th} data block, and continue to segment remaining data of the to-be-compressed data in a same manner.

It should be noted that, according to the data compression method provided in some embodiments, when a length of data obtained by compressing the to-be-compressed data is greater than the length limit value, the to-be-compressed data is segmented based on the length limit value in a process of compressing the to-be-compressed data. Accordingly, the to-be-compressed data includes at least two compressed files after compression, and a length of each compressed file is less than the length limit value. When the length of the data obtained by compressing the to-be-compressed data is less than or equal to the length limit value, the to-be-compressed data may be directly entirely compressed without performing the foregoing block division and prediction processes. It should be further noted that, when the to-be-compressed data is compressed into at least two compressed files, whose lengths are less than or equal to the length limit value, the terminal 100 may further obtain a complete compressed file, and perform decompression based on the complete compressed file, to restore the to-be-compressed data.

Based on the foregoing content description, some embodiments provide a data compression method. In the method, lengths of compressed data blocks are predicted, and the data blocks are merged and compressed based on prediction results, so that a length of compressed data is limited. For example, the length of the compressed data is limited within a target compression length, so that service requirements are met. In addition, according to the method, a length of the data blocks after merging and compression can be close to the target compression length, and an input of a maximum granularity may be achieved, thereby ensuring a high compression rate. Further, in the method, there is no need to repeatedly perform compression confirmation on same data, thereby ensuring compression performance. This method supports an automatic limitation on the length, and a user does not need to conduct a test manually, thereby simplifying user operations and improving user experience.

The following describes an example in which data compression is performed according to a compression algorithm based on entropy encoding and data compression is performed according to a compression algorithm based on duplicate content search.

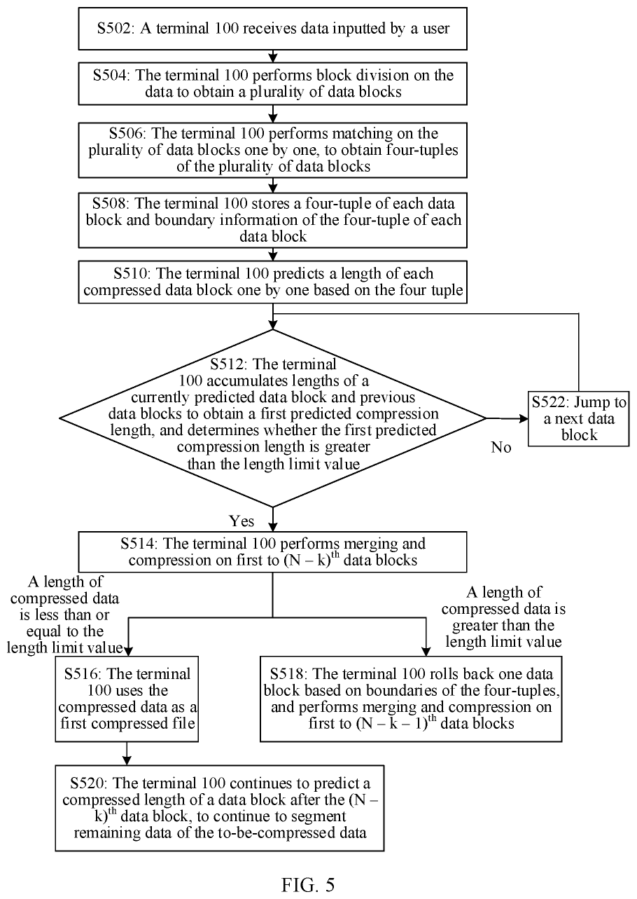

Refer to a schematic flowchart of a data compression method shown in FIG. 5, the method includes the following steps:

S502: A terminal 100 receives data inputted by a user.

S504: The terminal 100 performs block division on the data inputted by the user, to obtain a plurality of data blocks.

The terminal 100 may perform block division on the inputted data according to an average block division method, to obtain the plurality of data blocks. Further, the terminal 100 may further determine, based on match offsets obtained by performing matching on the data blocks, quantities of intersections of boundaries of the data blocks and matches, determine an optimal position for block division based on the quantities of intersections, and merge the data blocks based on the position for block division to obtain final data blocks.

S506: The terminal 100 performs matching on the plurality of data blocks one by one according to an LZ encoding algorithm, to obtain four-tuples of the plurality of data blocks.

The four-tuple includes an unmatched character, an unmatched character length, a match length, and a match offset. The unmatched character refers to a character sequence before the matching starts, the unmatched character length refers to a length of the character sequence before the matching starts, and the match length refers to a length of a match character sequence. The match offset refers to an offset of the match character sequence relative to a matched character sequence in the unmatched character.

For ease of understanding, descriptions are made below with reference to an example. Assuming that a data block includes a character sequence “ASDFGSDFKHJ”, the terminal 100 may determine that an unmatched character is “ASDFG”, an unmatched character length is 5, and a match character sequence is “SDF”. Based on this, a match length is 3. An offset from “SDF” after “ASDFG” to “SDF” in “ASDFG” is 4. Based on this, a match offset is 4. In this case, a first four-tuple may be denoted as (“ASDFG”, 5, 3, 4). Then, the terminal 100 continues to perform matching on remaining characters. Specifically, matching is performed on each character from right to left. In this way, a second four-tuple (“KHJ”, 3, 0, 0) may be determined.

It should be noted that, the foregoing example describes an intra-block four-tuple. The terminal 100 may further perform matching across the data blocks to obtain an inter-block four-tuple. For example, when other data blocks are further included before the foregoing data block, the foregoing data block may continue to be matched with the data blocks before the foregoing data block, to obtain the inter-block four-tuple.

S508: The terminal 100 stores a four-tuple of each data block and boundary information of the four-tuple of each data block.

The terminal 100 may store the four-tuples generated in a matching process so that it may manage process data including the four-tuples. Further, the terminal 100 may further store the boundary information of the four-tuples. For example, a quantity of four-tuples generated when performing matching on a data block, so that the data block can be quickly rolled back based on the boundary information upon subsequent data block rollback.

S510: The terminal 100 predicts a length of each compressed data block one by one based on the four-tuple.

The terminal 100 may separately perform character frequency statistics on each element in the four-tuples of the data blocks, and obtain an occurrence probability of a character by dividing the character frequency by a total quantity of the characters. Then, the length is predicted based on a Shannon-Fano entropy limit and an entropy encoding input. An entropy value prediction process includes a character frequency statistics process and an entropy value calculation process, where the entropy value calculation process consumes a short time that is neglible. In an entropy encoding process, compared with operations such as table creation and encoding which occupy more than 90% of a consumed time, character frequency statistics only occupy a short time, that is, a time for predicting the length is far less than an actual compression time. Compression efficiency can be effectively improved by first predicting and then compressing.

It should be noted that, entropy encoding may be separately performed on each element by separately performing character frequency statistics on each element of the four-tuples. For an element with a small quantity of characters, an occurrence probability of the character may be effectively improved, so that an encoding effect of the corresponding element can be improved.

S512: The terminal 100 accumulates lengths of a currently predicted data block and data blocks before the currently predicted data block to obtain a first predicted compression length, and determines whether the first predicted compression length is greater than the length limit value. When the first predicted compression length is greater than the length limit value, S514 is performed. When the first predicted compression length is less than or equal to the length limit value, S522 is performed.

S514: The terminal 100 first performs merging and compression on a first data block to an (N−k)^{th} data block. When a length of compressed data is less than or equal to the length limit value, S516 is performed. When the length of the compressed data is greater than the length limit value, S518 is performed.

The terminal 100 may perform entropy encoding on the data blocks based on four-tuples of the first data block to the (N−k)^{th} data block so as to implement merging and compression on the data blocks.

S516: The terminal 100 uses the compressed data as a first compressed file.

S518: The terminal 100 rolls back one data block based on boundaries of the four-tuples, and performs merging and compression on a first data block to an (N−k−1)^{th} data blocks.

S520: The terminal 100 continues to predict a length of a compressed data block after the (N−k)^{th} data block, to continue to segment remaining data of the to-be-compressed data.

S522: The terminal 100 jumps to a next data block and then performs S512.

For implementations of S512 to S522, refer to the related content descriptions in the embodiment shown in FIG. 2. Details are not described herein again.

FIG. 5 describes an example in which data compression is performed according to a compression algorithm based on entropy encoding. The following describes an example in which data compression is performed according to a compression algorithm based on duplicate content search.

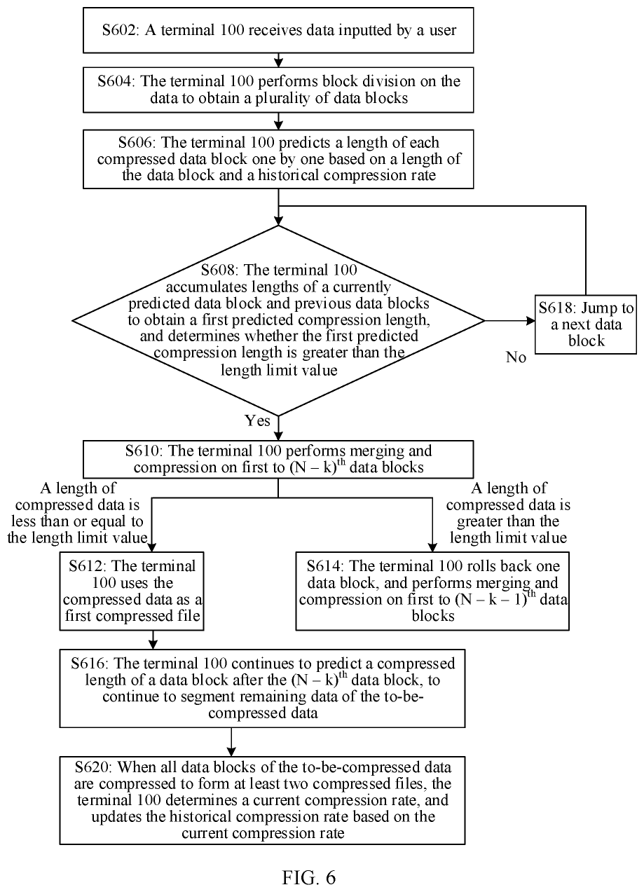

Refer to a schematic flowchart of a data compression method shown in FIG. 6, the method includes:

S602. A terminal 100 receives data inputted by a user.

S604: The terminal 100 performs block division on the data inputted by the user, to obtain a plurality of data blocks.

For implementations of S602 to S604, refer to the foregoing related content descriptions. Details are not described herein again.

S606: The terminal 100 predicts a length of each compressed data block one by one based on a length of the data block and a historical compression rate.

The terminal 100 maintains an overall compression rate corresponding to each compression process, and overall compression rates before current compression may be collectively referred to as a historical compression rate. The terminal 100 may predict the length of the compressed data block based on an average value of latest n compression rates and the length of the data block.

S608: The terminal 100 accumulates lengths of a currently predicted data block and data blocks before the currently predicted data block to obtain a first predicted compression length, and determines whether the first predicted compression length is greater than the length limit value. When the first predicted compression length is greater than the length limit value, S610 is performed. When the first predicted compression length is less than or equal to the length limit value, S618 is performed.

S610: The terminal 100 performs merging and compression on a first data block to an (N−k)^{th} data block. When a length of compressed data is less than or equal to the length limit value, S612 is performed. When the length of the compressed data is greater than the length limit value, S614 is performed.

S612: The terminal 100 uses the compressed data as a first compressed file and then performs S616.

S614: The terminal 100 rolls back one data block, and performs merging and compression on a first data block to an (N−k−1)^{th} data block.

The terminal 100 may perform merging and compression on the first data block to the (N−k−1) data block according to the compression algorithm based on duplicate content search.

S616: The terminal 100 continues to predict a length of a compressed data block after the (N−k)^{th} data block, to continue to segment remaining data of the to-be-compressed data.

S618: The terminal 100 jumps to a next data block and then performs S608.

S620: When all data blocks of the to-be-compressed data are compressed to form at least two compressed files, the terminal 100 determines a current compression rate, and updates the historical compression rate based on the current compression rate.

the terminal 100 may determine the current compression rate based on a length of the to-be-compressed data and a total length of the compressed files, and then maintain the current compression rate in a database or a data table, to update the historical compression rate.

The foregoing describes in detail the data compression methods provided in embodiments of this application with reference to FIG. 1 to FIG. 6. The following describes an apparatus provided in embodiments of this application with reference to the accompanying drawings.

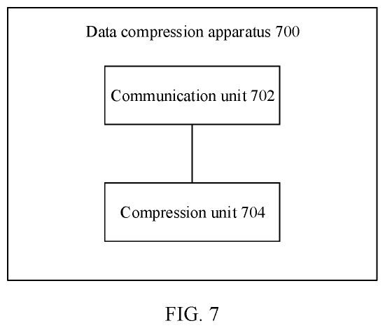

Referring. to a schematic diagram of a structure of a data compression apparatus shown in FIG. 7, the data compression apparatus 700 may be a software apparatus that includes a software unit module with a data compression function. Alternatively, the data compression apparatus 700 may be a hardware apparatus including a hardware unit module or circuit with a corresponding function. The apparatus 700 includes a communication unit 702 (e.g., communication circuit) and a compression unit 704 (e.g., compression circuit).

The communication unit 702 is configured to obtain to-be-compressed data and a length limit value for data compression.

For an implementation in which the communication unit 702 obtains the to-be-compressed data and the length limit value for data compression, refer to the related content descriptions of S202 in the embodiment shown in FIG. 2. Details are not described herein again.

The compression unit 704 is configured to, when a length of data obtained by compressing the to-be-compressed data is greater than the length limit value, segment the to-be-compressed data based on the length limit value in a process of compressing the to-be-compressed data, so that the to-be-compressed data includes at least two compressed files after compression, and a length of each compressed file is less than the length limit value.

For an implementation in which the compression unit 704 segments the to-be-compressed data based on the length limit value in the process of compressing the to-be-compressed data, so that the to-be-compressed data includes at least two compressed files after compression, refer to the related content descriptions of S204 to S218 in the embodiment shown in FIG. 2. Details are not described herein again.

In some possible implementations, the compression unit 704 is configured to predict a length of each compressed data block one by one, and accumulate lengths of a currently predicted data block and data blocks before the currently predicted block to obtain a first predicted compression length. When the first predicted compression length is greater than the length limit value, the compression unit 704 is further configured to perform compression based on the data blocks before the currently predicted data block. The compressed data forms a first compressed file, and the first compressed file belongs to the at least two compressed files.

For an implementation in which the compression unit 704 predicts the length of each compressed data block, and accumulates the lengths of the currently predicted data block and the data blocks before the currently predicted block to obtain the first predicted compression length, refer to the related content descriptions of S206 to S208. Details are not described herein again.

For an implementation in which the compression unit 704 performs compression based on the data blocks before the currently predicted data block and the compressed data forms the first compressed file, refer to the related content descriptions of S210 and S214. Details are not described herein again.

In some possible implementations, there are N data blocks before the currently predicted data block, and the compression unit 704 is configured to perform merging and compression on a first data block to an (N−k)^{th} data block, where N is a natural number greater than or equal to 2, and k is a natural number less than N. When a length of the compressed data is less than or equal to the length limit value, the compression unit 704 is further configured to use the compressed data as the first compressed file.

For an implementation in which the compression unit 704 performs merging and compression on the first data block to the (N−k)^{th} data block, and when the length of the compressed data is less than or equal to the length limit value, uses the compressed data as the first compressed file, refer to the related content descriptions of S210 and S214. Details are not described herein again.

In some possible implementations, the compression unit 704 is further configured to continue to predict a length of a compressed data block after the (N−k)^{th} data block, to continue to segment remaining data of the to-be-compressed data.

For an implementation in which the compression unit 704 continues to predict the length of the compressed data block after the (N−k)^{th} data block, to continue to segment the remaining data of the to-be-compressed data, refer to the related content descriptions of S218. Details are not described herein again.

In some possible implementations, there are N data blocks before the currently predicted data block, and the compression unit is configured to perform merging and compression on a first data block to an (N−k)^{th} data block, where N is a natural number greater than or equal to 2, and k is a natural number less than N. When a length of the compressed data is greater than the length limit value, the compression unit 704 is further configured to perform merging and compression on a first data block to an (N−k−1)^{th} data block.

For an implementation in which the compression unit 704 performs merging and compression on the first data block to the (N−k)^{th} data block, and when the length of the compressed data is greater than the length limit value, performs merging and compression on the first data block to the (N−k−1)^{th} data block, refer to the related content descriptions of S210 and S216. Details are not described herein again.

The data compression apparatus 700 according to embodiments of this application may correspondingly perform the methods described in embodiments of this application, and the foregoing and other operations and/or functions of the modules/units of the data compression apparatus 700 are separately configured to implement corresponding procedures of the methods in the embodiment shown in FIG. 2. For brevity, details are not described herein again.

An embodiment of this application further provides a device. The device is configured to implement functions of the data processing apparatus 700 in the embodiment shown in FIG. 7. The device may be a terminal such as a notebook computer or a desktop computer, or may be a local server or a cloud server. For ease of understanding, an example in which the device is a terminal is used for description.

Refer to a schematic diagram of a structure of a terminal 100 shown in FIG. 1, the terminal 100 includes a bus 101, a processor 102, a communication interface 103, and a memory 104. The processor 102, the memory 104, and the communication interface 103 communicate with each other through the bus 101.

The communication interface 103 is configured to communicate with the outside. For example, the communication interface 103 is configured to obtain to-be-compressed data, obtain a length limit value for data compression, or output at least two compressed files whose lengths are less than the length limit value, or the like. The memory 104 stores executable code, and the processor 102 executes the executable code to perform the foregoing data compression method.

An embodiment of this application further provides a computer-readable storage medium. The computer-readable storage medium includes instructions, and the instructions instruct a computer to perform the foregoing data compression methods applied to the data compression apparatus 700.

An embodiment of this application further provides a computer-readable storage medium. The computer-readable storage medium includes instructions, and the instructions instruct a computer to perform the foregoing data compression methods applied to the data compression apparatus 700.

An embodiment of this application further provides a computer program product. When the computer program product is executed by a computer, the computer performs any method of the foregoing data compression methods. The computer program product may be a software installation package. In a case that any method of the foregoing data compression methods needs to be used, the computer program product may be downloaded and the computer program product is executed by a computer.

What is claimed is:

1. A data compression method, wherein the method comprises:
obtaining to-be-compressed data and a length limit value for data compression; and
when a length of data obtained by compressing the to-be-compressed data is greater than the length limit value, segmenting the to-be-compressed data based on the length limit value in a process of compressing the to-be-compressed data, wherein the to-be-compressed data comprises at least two compressed files after compression and a length of each compressed file is less than the length limit value.

2. The method according to claim 1, wherein the segmenting of the to-be-compressed data based on the length limit value comprises:
predicting a length of each compressed data block, and accumulating a length of a currently predicted data block and lengths of data blocks before the currently predicted data block to obtain a first predicted compression length; and
when the first predicted compression length is greater than the length limit value, performing the compression based on the data blocks before the currently predicted data block, wherein:
compressed data forms a first compressed file, and
the first compressed file belongs to the at least two compressed files.

3. The method according to claim 2, wherein there are N data blocks before the currently predicted data block and the performing of the compression based on the data blocks before the currently predicted data block comprises:
performing merging and compression from a first data block to an (N−k)^{th} data block, wherein:
N is a natural number greater than or equal to 2, and k is a natural number less than N; and
when a length of the compressed data is less than or equal to the length limit value, using the compressed data as the first compressed file.

4. The method according to claim 3, wherein the method further comprises:
continuing to predict the length of the compressed data block after the (N−k)^{th} data block so as to continue to segment remaining data of the to-be-compressed data.

5. The method according to claim 2, wherein there are N data blocks before the currently predicted data block, and the performing of the compression based on the data blocks before the currently predicted data block comprises:
performing merging and compression from a first data block to an (N−k)^{th} data block, wherein:
N is a natural number greater than or equal to 2, and k is a natural number less than N; and
when a length of the compressed data is greater than the length limit value, performing merging and compression from a first data block to an (N−k−1)^{th} data block.

6. A data compression apparatus, wherein the apparatus comprises:
at least one processor; and
one or more memories coupled to the at least one processor and storing programming instructions for execution by the at least one processor to perform operations comprising:
obtaining to-be-compressed data and a length limit value for data compression; and
when a length of data obtained by compressing the to-be-compressed data is greater than the length limit value, segmenting the to-be-compressed data based on the length limit value in a process of compressing the to-be-compressed data, wherein the to-be-compressed data comprises at least two compressed files after compression and a length of each compressed file is less than the length limit value.

7. The apparatus according to claim 6, wherein the segmenting of the to-be-compressed data based on the length limit value comprises:
predicting a length of each compressed data block, and accumulating a length of a currently predicted data block and lengths of data blocks before the currently predicted data block to obtain a first predicted compression length; and
when the first predicted compression length is greater than the length limit value, performing the compression based on the data blocks before the currently predicted data block, wherein compressed data forms a first compressed file, and the first compressed file belongs to the at least two compressed files.

8. The apparatus according to claim 7, wherein there are N data blocks before the currently predicted data block and the performing of the compression based on the data blocks before the currently predicted data block comprises:
performing merging and compression from a first data block to an (N−k)^{th} data block, wherein:
N is a natural number greater than or equal to 2, and k is a natural number less than N; and
when a length of the compressed data is less than or equal to the length limit value, using the compressed data as the first compressed file.

9. The apparatus according to claim 8, wherein the operations further comprises:
continuing to predict the length of the compressed data block after the (N−k)^{th} data block so as to continue to segment remaining data of the to-be-compressed data.

10. The method according to claim 7, wherein there are N data blocks before the currently predicted data block, and the performing of the compression based on the data blocks before the currently predicted data block comprises:
performing merging and compression from a first data block to an (N−k)^{th} data block, wherein:
N is a natural number greater than or equal to 2, and k is a natural number less than N; and
when a length of the compressed data is greater than the length limit value, performing merging and compression from a first data block to an (N−k−1)^{th} data block.

11. A non-transitory computer-readable storage medium, wherein the computer-readable storage medium stores a computer program; and when the computer program is executed on a computer, the computer is enabled to perform the method of:
obtaining to-be-compressed data and a length limit value for data compression; and
when a length of data obtained by compressing the to-be-compressed data is greater than the length limit value, segmenting the to-be-compressed data based on the length limit value in a process of compressing the to-be-compressed data, wherein the to-be-compressed data comprises at least two compressed files after compression and a length of each compressed file is less than the length limit value.

12. The computer-readable storage medium according to claim 11, wherein the segmenting of the to-be-compressed data based on the length limit value comprises:
predicting a length of each compressed data block, and accumulating a length of a currently predicted data block and lengths of data blocks before the currently predicted data block to obtain a first predicted compression length; and
when the first predicted compression length is greater than the length limit value, performing the compression based on the data blocks before the currently predicted data block, wherein compressed data forms a first compressed file, and the first compressed file belongs to the at least two compressed files.

13. The computer-readable storage medium according to claim 12, wherein there are N data blocks before the currently predicted data block, and the performing of the compression based on the data blocks before the currently predicted data block comprises:
performing merging and compression from a first data block to an (N−k)^{th} data block, wherein:
N is a natural number greater than or equal to 2, and k is a natural number less than N; and
when a length of the compressed data is less than or equal to the length limit value, using the compressed data as the first compressed file.

14. The computer-readable storage medium according to claim 13, wherein the method further comprises:
continuing to predict the length of the compressed data block after the (N−k)^{th} data block so as to continue to segment remaining data of the to-be-compressed data.

15. The computer-readable storage medium according to claim 12, wherein there are N data blocks before the currently predicted data block, and the performing of the compression based on the data blocks before the currently predicted data block comprises:
performing merging and compression from a first data block to an (N−k)^{th} data block, wherein:
N is a natural number greater than or equal to 2, and k is a natural number less than N; and
when a length of the compressed data is greater than the length limit value, performing merging and compression on a first data block to an (N−k−1)^{th} data block.

16. A device comprising a processor and a memory that is communicatively coupled to the processor, the processor being configured to implement the method according to claim 1.
